(19) United States
(12) Patent Application Publication
(10) Pub. No.: US 2019/0006540 A1
(43) Pub. Date: Jan. 3, 2019

(54) SOLAR CELL

(71) Applicant: Panasonic Corporation, Osaka (JP)

(72) Inventors: TAKASHI NISHIHARA, Osaka (JP); SHINYA FUJIMURA, Osaka (JP); TAKAYUKI NEGAMI, Osaka (JP)

(21) Appl. No.: 16/000,923

(22) Filed: Jun. 6, 2018

(30) Foreign Application Priority Data
Jun. 30, 2017 (JP) 2017-128545

(51) Int. Cl. H01L 31/0224; H01L 51/42; H01L 51/00; H01L 51/44; H01L 31/0445

(52) U.S. Cl. CPC H01L 31/022466; H01L 51/4226; H01L 31/0445; H01L 51/447; H01L 31/022425; H01L 51/0032

(57) ABSTRACT

A solar cell includes: a first electrode; a hole transport layer containing nickel, lithium, and oxygen; a light-absorbing layer converting light into electric charge; and a second electrode. The first electrode, the hole transport layer, the light-absorbing layer, and the second electrode are layered in that order. The light-absorbing layer contains a perovskite compound represented by a formula AMX₃, where A is a monovalent cation, M is a divalent cation, and X is a monovalent anion. A concentration of lithium in a first portion of the hole transport layer is less than a concentration of lithium in a second portion of the hole transport layer, the first portion facing the light-absorbing layer, the second portion facing the first electrode.

### BACKGROUND

### 1. Technical Field

The present disclosure relates to solar cells. The present disclosure particularly relates to a solar cell in which a perovskite-type crystal is used as a light-absorbing material.

### 2. Description of the Related Art

In recent years, solar cells in which a compound (hereinafter referred to as “perovskite compound”) having a perovskite crystal structure represented by the formula AMX₃ or a similar crystal structure is used as a light-absorbing material have been researched and developed. Herein, a solar cell containing the perovskite compound is referred to as “perovskite solar cell”.

Wei Chen et al., Science (United States), vol. 350, no. 6263 (November 2015), pp. 944-948 (hereinafter referred to as the “non-patent document”) discloses a perovskite solar cell in which CH₃NH₃PbI₃ is used as a perovskite material, nickel oxide doped with lithium and magnesium is used as a hole transport material, and [6,6]-phenyl-C61-butyric acid methyl ester (PCBM) is used as an electron transport material and which has an inverted stack structure.

### SUMMARY

One non-limiting and exemplary embodiment provides a solar cell capable of having high photoelectric conversion efficiency.

In one general aspect, the techniques disclosed here feature a solar cell including a first electrode; a hole transport layer containing nickel, lithium, and oxygen; a light-absorbing layer converting light into electric charge; and a second electrode. The first electrode, the hole transport layer, the light-absorbing layer, and the second electrode are layered in that order. The light-absorbing layer contains a perovskite compound represented by a formula AMX₃, where A is a monovalent cation, M is a divalent cation, and X is a monovalent anion. A concentration of lithium in a first portion of the hole transport layer is less than a concentration of lithium in a second portion of the hole transport layer, the first portion facing the light-absorbing layer, the second portion facing the first electrode.

It should be noted that general or specific embodiments may be implemented as an element, a device, a module, a system, an integrated circuit, or a method. It should be noted that general or specific embodiments may be implemented as any selective combination of an element, a device, a module, a system, an integrated circuit, and a method.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic sectional view of a solar cell according to a first embodiment of the present disclosure;

FIG. 2 is a schematic sectional view of a solar cell according to a second embodiment of the present disclosure;

FIG. 3A is a graph showing results obtained by analyzing elements in a solar cell of Example 1 in the depth direction;

FIG. 3B is a graph showing results obtained by analyzing elements in a solar cell of Comparative Example 1 in the depth direction; and

FIG. 4 is a graph showing the current-voltage characteristic of each of solar cells of Example 1 and Comparative Example 1.

### DETAILED DESCRIPTION

Underlying knowledge forming the basis of the present disclosure is as described below.

Perovskite solar cells (hereinafter simply referred to as “solar cells”) are classified into a regular stack structure and an inverted stack structure. In the regular stack structure, an electron transport layer is placed on the light-incident side of a light-absorbing layer (hereinafter referred to as the “perovskite layer”) containing a perovskite compound. For example, the electron transport layer, the perovskite layer, a hole transport layer, and an upper electrode (for example, a metal electrode) are placed on a transparent electrode in that order. In the inverted stack structure, a hole transport layer is placed on the light-incident side of a perovskite layer. For example, the hole transport layer, the perovskite layer, an electron transport layer, and an upper electrode are placed on a transparent electrode in that order.

In the regular stack structure, since the hole transport layer is formed after the formation of the perovskite layer, an organic material formable by a low-temperature process is usually used as a material (hole transport material) for the hole transport layer. In contrast, in the inverted stack structure, since the hole transport layer is formed before the formation of the perovskite layer, the hole transport layer can be formed at relatively high temperature and an inorganic material can be used as a hole transport material.

For example, the non-patent document discloses that nickel oxide doped with lithium is used as a hole transport material. A NiO layer can be increased in carrier density by substituting a portion of a nickel site (divalent side) of nickel oxide (NiO) with mono valent lithium.

However, investigations carried out by the inventor have shown that a NiO layer doped with Li has lower crystallinity and higher defect density as compared to a NiO layer containing no Li. Therefore, using the NiO layer doped with lithium as a hole transport layer in contact with a perovskite layer increases the recombination of carriers at the interface between the hole transport layer and the perovskite layer, leading to a possibility that high photoelectric conversion efficiency is not obtained.

The inventor has carried out investigations on the basis of the above finding and, as a result, has found a novel structure capable of suppressing the recombination of carriers at the interface between a hole transport layer and a perovskite layer.

The present disclosure includes a solar cell specified in items below.

### Item 1

A solar cell includes

a first electrode;

a hole transport layer containing nickel, lithium, and oxygen;

a light-absorbing layer converting light into electric charge; and

a second electrode, wherein

the first electrode, the hole transport layer, the light-absorbing layer, and the second electrode are layered in that order,

the light-absorbing layer contains a perovskite compound represented by a formula AMX₃, where A is a monovalent cation, M is a divalent cation, and X is a monovalent anion, and

a concentration of lithium in a first portion of the hole transport layer is less than a concentration of lithium in a second portion of the hole transport layer, the first portion facing the light-absorbing layer, the second portion facing the first electrode.

### Item 2

In the solar cell specified in Item 1, the hole transport layer includes a first hole transport layer located on a side of the first electrode and a second hole transport layer located on a side of the light-absorbing layer, and

an atomic ratio of lithium to all metal elements in the second hole transport layer is less than an atomic ratio of lithium to all metal elements in the first hole transport layer.

### Item 3

In the solar cell specified in Item 1, the hole transport layer includes a first hole transport layer located on a side of the first electrode and a second hole transport layer located on a side of the light-absorbing layer,

the first hole transport layer contains lithium, and

the second hole transport layer contains substantially no lithium.

### Item 4

In the solar cell specified in Item 2 or 3, at least either the first hole transport layer or the second hole transport layer further contains magnesium.

### Item 5

In the solar cell specified in any one of Items 2 to 4, a thickness of the second hole transport layer is less than a thickness of the first hole transport layer.

### Item 6

In the solar cell specified in any one of Items 2 to 5, a thickness of the second hole transport layer is 1 nm or more and 10 nm or less.

### Item 7

In the solar cell specified in Item 6, the thickness of the second hole transport layer is 2 nm or more and 5 nm or less.

### Item 8

In the solar cell specified in any one of Items 2 to 7, an atomic ratio of lithium to all the metal elements in the first hole transport layer is 1% or more and 30% or less.

### Item 9

In the solar cell specified in Item 8, the atomic ratio of lithium to all the metal elements in the first hole transport layer is 5% or more and 20% or less.

### Item 10

In the solar cell specified in any one of Items 1 to 9, in concentration profiles of nickel and lithium in a depth direction of the hole transport layer, a peak corresponding to nickel is located closer to the light-absorbing layer than a peak corresponding to lithium is.

### Item 11

A solar cell includes

a first electrode;

a hole transport layer containing nickel, lithium, and oxygen;

a light-absorbing layer converting light into electric charge; and

a second electrode, wherein

the first electrode, the hole transport layer, the light-absorbing layer, and the second electrode are layered in that order,

the light-absorbing layer contains a perovskite compound represented by a formula AMX₃, where A is a monovalent cation, M is a divalent cation, and X is a monovalent anion, and

in concentration profiles of nickel and lithium in a depth direction of the hole transport layer, a peak corresponding to nickel is located closer to the light-absorbing layer than a peak corresponding to lithium is.

Embodiments of the present disclosure are described below with reference to the accompanying drawings.

### First Embodiment

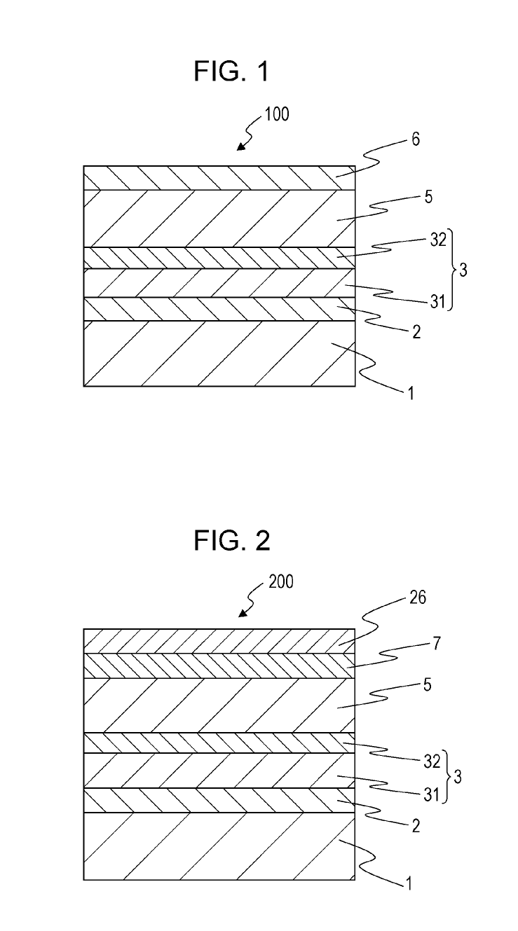

FIG. 1 is a schematic sectional view of a solar cell 100 according to a first embodiment of the present disclosure.

As shown in FIG. 1, the solar cell 100 includes a substrate 1, a first electrode 2, a hole transport layer 3, a light-absorbing layer 5, and a second electrode 6.

The first electrode 2 is light-transmissive and therefore light enters the solar cell 100 from the substrate 1 side. The hole transport layer 3 is placed on the light-incident side of the light-absorbing layer 5. Thus, the solar cell 100 has an inverted stack structure.

The hole transport layer 3 has a multilayer structure including a first hole transport layer 31 and a second hole transport layer 32 placed between the first hole transport layer 31 and the light-absorbing layer 5. The first hole transport layer 31 contains nickel, lithium, and oxygen. The second hole transport layer 32 contains nickel and oxygen. The second hole transport layer 32 may further contain lithium or may contain substantially no lithium. The expression “contain substantially no lithium” means that the second hole transport layer 32 is formed without intentionally adding lithium. The expression “contain substantially no lithium” also means that the content of lithium is, for example, less than 0.05% by weight. When the second hole transport layer 32 contains lithium, the atomic ratio (hereinafter simply referred to as the “lithium ratio” in some cases) of lithium to all metal elements in the second hole transport layer 32 is less than the lithium ratio in the first hole transport layer 31.

The light-absorbing layer 5 converts light into electric charge. The light-absorbing layer 5 contains a perovskite compound represented by the formula AMX₃, where A is a monovalent cation, M is a divalent cation, and X is a monovalent anion.

Fundamental action effects of the solar cell 100 are described below.

When the solar cell 100 is irradiated with light, the light-absorbing layer 5 absorbs light to generate excited electrons and holes. The excited electrons migrate to the second electrode 6. On the other hand, the holes generated in the light-absorbing layer 5 migrate to the first hole transport layer 31 through the second hole transport layer 32. Since the first hole transport layer 31 is connected to the first electrode 2, a current can be extracted from the solar cell 100 in such a manner that the first electrode 2 is used as a positive electrode and the second electrode 6 is used as a negative electrode.

In this embodiment, the second hole transport layer 32 is placed on the light-absorbing layer 5 side of the first hole transport layer 31. Since the second hole transport layer 32 has a lithium ratio less than that of the first hole transport layer 31, the crystallinity of the second hole transport layer 32 can be maintained higher than that of the first hole transport layer 31 and the defect density of the second hole transport layer 32 can be reduced to a level lower than that of the first hole transport layer 31. Therefore, the recombination of carriers at the interface between the hole transport layer 3 and the light-absorbing layer 5 can be suppressed; hence, the photoelectric conversion efficiency of the solar cell 100 can be increased.

The first hole transport layer 31 and the second hole transport layer 32 may be made of nickel oxide or a material obtained by substituting a portion of nickel in nickel oxide with lithium and the substitution amount of lithium in the second hole transport layer 32 may be less than the substitution amount of lithium in the first hole transport layer 31. This allows the number of carrier recombination centers present in the second hole transport layer 32 to be less than that in the first hole transport layer 31. Placing the second hole transport layer 32 on the light-absorbing layer 5 side of the first hole transport layer 31 enables the possibility that the holes generated in the light-absorbing layer 5 are lost by recombination at the interface between the hole transport layer 3 and the light-absorbing layer 5 to be reduced.

The amount of lithium doped in the second hole transport layer 32 may be less than that in the first hole transport layer 31. This enables, for example, the level of the valence band of the second hole transport layer 32 to be set between the level of the valence band of the first hole transport layer 31 and the level of the valence band of the light-absorbing layer 5. Thus, holes can be readily moved from the light-absorbing layer 5 to the first electrode 2.

Components of the solar cell 100 are described below.

### Substrate 1

The substrate 1 is an auxiliary component of the solar cell 100. The substrate 1 physically supports stacked layers of the solar cell 100 in the form of a film when the solar cell 100 is configured. The substrate 1 is light-transmissive. The substrate 1 used may be, for example, a glass substrate, a plastic substrate (including a plastic film), or the like. In the case where the first electrode 2 can support the layers in the form of a film, the substrate 1 may be omitted.

### First Electrode 2

The first electrode 2 is electrically conductive. Furthermore, the first electrode 2 is light-transmissive. The first electrode 2 transmits, for example, visible light and near-infrared light. The first electrode 2 can be formed using a material such as a transparent, electrically conductive metal oxide. Examples of the transparent, electrically conductive metal oxide include an indium-tin composite oxide; tin oxide doped with antimony; tin oxide doped with fluorine; zinc oxide doped with boron, aluminium, gallium, or indium; and composites of these compounds. The first electrode 2 may be formed using an opaque material so as to have a light-transmissive pattern.

Examples of the light-transmissive pattern include a linear (striped) pattern, a wavy pattern, a grid (mesh) pattern, a punching metal-like pattern having a large number of fine through-holes arranged regularly or irregularly, and patterns obtained by positively or negatively inverting these patterns. When the first electrode 2 has the light-transmissive pattern, light can pass through a portion in which the opaque material is not present. Examples of the opaque material include platinum, gold, silver, copper, aluminium, rhodium, indium, titanium, iron, nickel, tin, zinc, and alloys containing either of these metals. Alternatively, an electrically conductive carbon material can be used.

The light transmittance of the first electrode 2 is, for example, 50% or more or may be 80% or more. The wavelength of light that should be transmitted depends on the absorption wavelength of the light-absorbing layer 5. The thickness of the first electrode 2 is within the range of, for example, 1 nm to 1,000 nm.

### Light-Absorbing Layer 5

The light-absorbing layer 5 contains the perovskite compound, which is represented by the formula AMX₃. The perovskite compound serves as a light-absorbing material. In the formula AMX₃, A is the monovalent cation. Examples of the monovalent cation include monovalent cations such as alkali metal cations and organic cations. Particular examples of the monovalent cation include a methylammonium cation (CH₃NH₃⁺), a formamidinium cation (NH₂CHNH₂⁺), a cesium cation (Cs⁺), and a rubidium cation (Rb⁺).

In the formula AMX₃, M is the divalent cation. Examples of the divalent cation include divalent cations of transition metals and group 13 to 15 elements. Particular examples of the divalent cation include Pb²⁺, Ge²⁺, and Sn²⁺. In the formula AMX₃, X is the monovalent anion. The monovalent anion is a halogen anion or the like.

The site of each of A, M, and X may be occupied by multiple types of ions. Examples of the perovskite compound include CH₃NH₃PbI₃, CH₃CH₂NH₃PbI₃, NH₂CHNH₂PbI₃, CH₃NH₃PbBr₃, CH₃NH₃PbCl₃, CsPbI₃, CsPbBr₃, RbPbI₃, and RbPbBr₃.

The thickness of the light-absorbing layer 5 depends on the magnitude of the light absorption thereof and is, for example, 100 nm to 1,000 nm. The light-absorbing layer 5 can be formed by a coating process using a solution, a co-deposition process, or the like. The light-absorbing layer 5 may be partly mixed with an electron transport layer.

### Hole Transport Layer 3

The hole transport layer 3 includes the first hole transport layer 31 and the second hole transport layer 32. The first hole transport layer 31 and the second hole transport layer 32 contain a semiconductor. The first hole transport layer 31 and the second hole transport layer 32 may be made of an inorganic p-type semiconductor. Examples of the inorganic p-type semiconductor include nickel oxide and materials obtained by substituting a portion of nickel in nickel oxide with another element. Examples of the other element include lithium and magnesium.

The first hole transport layer 31 may further contain lithium. The atomic ratio of lithium to all metal elements in the first hole transport layer 31 may be 1% to 30% or 5% to 20%. The first hole transport layer 31 may be made of a material obtained by substituting a portion of nickel in nickel oxide with lithium. Substituting a portion of nickel in nickel oxide with lithium enables the density of carriers to be increased and therefore enables the electrical conductivity to be increased. The amount of lithium substituting for nickel (that is, the substitution amount of lithium) is represented by, for example, the atomic ratio of lithium to all the metal elements in the first hole transport layer 31 and may be 1% to 30% or 5% to 20%. Setting the substitution amount of lithium within the above range enables the increase in electrical conductivity of the hole transport layer 3 and the ensuring of the light transmissivity thereof to be both achieved.

The first hole transport layer 31 may further contain magnesium. The atomic ratio of magnesium to all the metal elements in the first hole transport layer 31 may be 1% to 30% or 5% to 20%. The first hole transport layer 31 may be made of a material obtained by substituting a portion of nickel in nickel oxide with magnesium. Substituting a portion of nickel in nickel oxide with magnesium enables the light transmissivity of the first hole transport layer 31 to be increased and also enables the level of the valence band to be lowered, thereby enabling the hole transportability to be increased. The amount of magnesium substituting for nickel (that is, the substitution amount of magnesium) is represented by, for example, the atomic ratio of magnesium to all the metal elements in the first hole transport layer 31 and may be 1% to 30% or 5% to 20%. Setting the substitution amount of magnesium within the above range enables the crystallinity of the first hole transport layer 31 to be maintained high and also enables the light transmissivity and hole transportability of the first hole transport layer 31 to be increased.

The first hole transport layer 31 may contain both lithium and magnesium. The sum of the atomic ratio of lithium to all the metal elements in the first hole transport layer 31 and that of magnesium may be 1% to 30% or 5% to 20%. A portion of nickel in nickel oxide may be substituted with lithium and another portion thereof may be substituted with magnesium. In this case, the sum of the substitution amount of lithium and that of magnesium may be, for example, 1% to 30% or 5% to 20%.

The second hole transport layer 32 may be a nickel oxide layer containing substantially no lithium or may be made of a material obtained by substituting a portion of nickel in nickel oxide with lithium, magnesium, or both of lithium and magnesium. When the second hole transport layer 32 contains lithium, the lithium ratio (the sum of the atomic ratio of lithium to all metal elements and that of magnesium) of the second hole transport layer 32 is less than that of the first hole transport layer 31. This enables the reduction in crystallinity of the second hole transport layer 32 due to the addition of lithium to be suppressed as compared to that of first hole transport layer 31. The sum of the atomic ratio of lithium to all metal elements in the second hole transport layer 32 and that of magnesium may be, for example, 0% to 15% or 0% to 10%. This enables the electrical conductivity of the second hole transport layer 32 to be ensured and also enables the crystallinity thereof to be increased.

The second hole transport layer 32, as well as the first hole transport layer 31, may contain magnesium. This enables the light transmissivity to be increased and also enables the level of the valence band to be lowered. The range of the atomic ratio of magnesium to all the metal elements in the second hole transport layer 32 may be substantially the same as that in the first hole transport layer 31.

In a regular stack structure, an organic material formable by a low-temperature process is usually used in a hole transport layer as described above. In the regular stack structure, if a metal element such as Li or Mg is added to the organic material, which makes up the hole transport layer, Li or the like may possibly be diffused in a light-absorbing layer by an increase in temperature to reduce the reliability of a solar cell. However, in the inverted stack structure, since the hole transport layer 3 is formed before the light-absorbing layer 5 is formed, the hole transport layer 3 can be formed at a relatively high temperature and an inorganic material can be used to form the hole transport layer 3. Even if a metal element, such as Li or Mg, serving as a substitution element is added to the inorganic material used to form the hole transport layer 3, Li or the like is unlikely to be diffused in the light-absorbing layer 5. This is because, in the inverted stack structure, the hole transport layer 3 is formed at a relatively high temperature and therefore an added element such as Li or Mg is placed at the lattice position of an original metal element by substitution. Thus, the reliability of a solar cell can be ensured and the hole transportability can be improved.

The thickness of the first hole transport layer 31 may be 1 nm to 50 nm or 5 nm to 20 nm. Setting the thickness of the first hole transport layer 31 within such a range enables the resistance of the first hole transport layer 31 to be kept low and also enables the hole transportability of the first hole transport layer 31 to be sufficiently exhibited.

The thickness of the second hole transport layer 32 may be less than that of the first hole transport layer 31. This enables an increase in electrical resistance due to the formation of the second hole transport layer 32 to be suppressed. The lower limit of the thickness of the second hole transport layer 32 is not particularly limited. When the thickness of the second hole transport layer 32 is, for example, 1 nm or more, the recombination of carriers at the interface between the hole transport layer 3 and the light-absorbing layer 5 can be effectively suppressed.

The thickness of the second hole transport layer 32 may be 1 nm to 10 nm or 2 nm to 5 nm. Setting the thickness of the second hole transport layer 32 within such a range enables the resistance of the first hole transport layer 31 to be kept low and also enables the hole transportability of the second hole transport layer 32 to be sufficiently exhibited.

A coating process or a printing process can be used to form the hole transport layer 3 (the first hole transport layer 31 and the second hole transport layer 32). Examples of the coating process include a doctor blade process, a bar-coating process, a spraying process, a dip coating process, and a spin coating process. An example of the printing process is a screen printing process. The hole transport layer 3 may be prepared using a mixture of multiple materials, followed by pressing or firing as required. When the hole transport layer 3 is made of a low-molecular-weight organic substance or an inorganic semiconductor, the hole transport layer 3 can be prepared by a vacuum vapor deposition process or a sputtering process.

In this embodiment, the hole transport layer 3 is not limited to a two-layer structure including the first hole transport layer 31 and the second hole transport layer 32. The hole transport layer 3 may be formed such that the lithium ratio thereof is less on the light-absorbing layer 5 side than on the first electrode 2 side. The fact that the hole transport layer 3 has such a configuration can be confirmed by the fact that, for example, in the concentration profiles of nickel and lithium in the depth direction thereof, a peak corresponding to nickel is located closer to the light-absorbing layer 5 than a peak corresponding to lithium. The hole transport layer 3 may have, for example, a multilayer structure composed of three or more layers including the first hole transport layer 31 and the second hole transport layer 32. Alternatively, the hole transport layer 3 need not have any multilayer structure. The hole transport layer 3 may be, for example, a layer in which the lithium ratio (the atomic ratio of lithium to all metal elements) decreases stepwise or continuously from the substrate 1 side toward the light-absorbing layer 5 side. The hole transport layer 3 can be formed by, for example, a known process such as a spraying process, a spin coating process, or a sputtering process.

### Second Electrode 6

The second electrode 6 is electrically conductive. The second electrode 6 need not be light-transmissive. The second electrode 6 is placed so as to face the first electrode 2 with the light-absorbing layer 5 therebetween. That is, the second electrode 6 is placed opposite to the first electrode 2 with respect to the light-absorbing layer 5.

The second electrode 6 forms no ohmic contact with the light-absorbing layer 5. The second electrode 6 has the property of blocking holes from the light-absorbing layer 5. The property of blocking holes from the light-absorbing layer 5 is the property of transmitting only electrons generated in the light-absorbing layer 5 without transmitting holes. A material having such a property is a material with a Fermi level lower than the energy level of the valence band minimum of the light-absorbing layer 5. A particular example of such a material is aluminium.

### Second Embodiment

A solar cell 200 according to a second embodiment of the present disclosure is different from the solar cell 100 according to the first embodiment in that the solar cell 200 includes an electron transport layer 7.

The solar cell 200 is described below. Components having substantially the same function and configuration as those used to describe the solar cell 100 are given the same reference numerals and will not be described in detail.

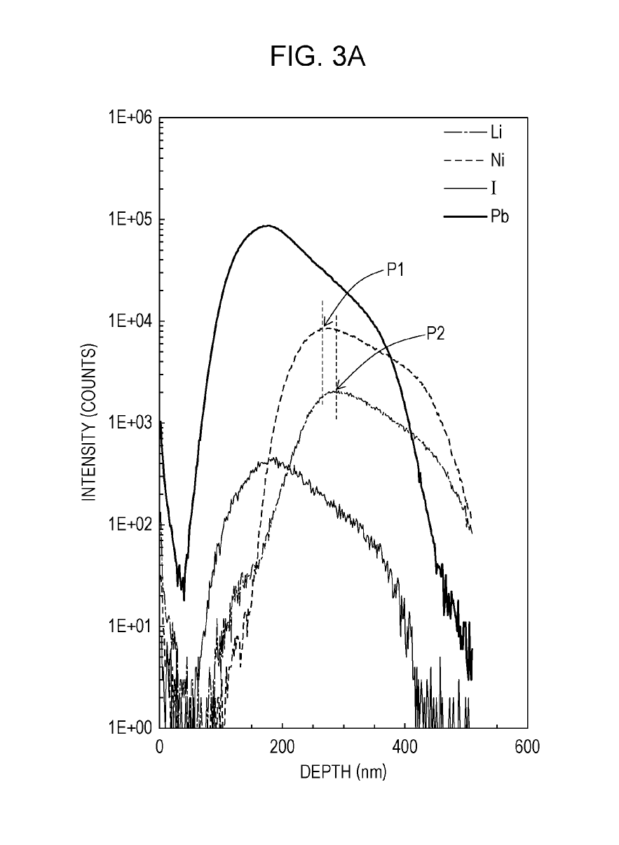

As shown in FIG. 2, the solar cell 200 includes a substrate 1, a first electrode 2, a first hole transport layer 3, a light-absorbing layer 5, and a second electrode 26 in addition to the hole transport layer 7. The electron transport layer 7 is located between the light-absorbing layer 5 and the second electrode 26.

Fundamental action effects of the solar cell 200 are described below.

When the solar cell 200 is irradiated with light, the light-absorbing layer 5 absorbs light to generate excited electrons and holes. The excited electrons migrate to the second electrode 26 through the electron transport layer 7. On the other hand, the holes generated in the light-absorbing layer 5 migrate to a first hole transport layer 31 through a second hole transport layer 32. Since the hole transport layer 3 is connected to the first electrode 2, a current can be extracted from the solar cell 200 in such a manner that the first electrode 2 is used as a positive electrode and the second electrode 26 is used as a negative electrode.

### Second Electrode 26

The second electrode 26 is electrically conductive. The second electrode 26 may have substantially the same configuration as that of the second electrode 6. In this embodiment, since the electron transport layer 7 is used, the second electrode 26 need not have the property of blocking holes from a perovskite compound. That is, the second electrode 26 may be made of a material making an ohmic contact with the perovskite compound.

### Electron Transport Layer 7

The electron transport layer 7 contains a semiconductor. In the electron transport layer 7, the semiconductor may have a band gap of 3.0 eV or more. Forming the electron transport layer 7 from a substance with a band gap of 3.0 eV or more enables visible light and infrared light to reach the light-absorbing layer 5. An example of the semiconductor is an organic or inorganic n-type semiconductor. Examples of the organic n-type semiconductor include imide compounds, quinone compounds, fullerene, and derivatives thereof. An inorganic semiconductor used may be, for example, an oxide of a metal element or a perovskite oxide. Examples of the metal element oxide include oxides of Cd, Zn, In, Pb, Mo, W, Sb, Bi, Cu, Hg, Ti, Ag, Mn, Fe, V, Sn, Zr, Sr, Ga, and Cr. A particular example of the metal element oxide is TiO₂. The perovskite oxide used may be, for example, SrTiO₃ or CaTiO₃. The electron transport layer 7 may be formed from a substance with a band gap of more than 6 eV. Examples of the substance with a band gap of more than 6 eV include alkali metal halides such as lithium fluoride, alkaline-earth metal halides such as calcium fluoride, alkali metal oxides such as magnesium oxide, and silicon dioxide. In this embodiment, in order to ensure the electron transportability of the electron transport layer 7, the electron transport layer 7 is configured to have a thickness of about 10 nm or less. The electron transport layer 7 may have a multilayer structure including multiple layers made of different materials.

### Method for Analyzing Solar Cell

For a solar cell having such a configuration as described in the above embodiments, techniques below are cited as methods for determining elements in layers and the thickness of each layer.

An element can be analyzed in the depth direction of each layer. For example, time-of-flight secondary ion mass spectrometry (TOF-SIMS) is cited as a method for analyzing an element in the depth direction.

The thickness of each layer can be determined in such a manner that, for example, a sample, microfabricated using a focused ion beam (FIB) or the like, having a measurable cross-sectional shape is observed with an electron microscope such as a scanning electron microscope (SEM) or a transmission electron microscope (TEM). Elements in the layer can be determined by elemental analysis by energy dispersive X-ray spectrometry (EDS) performed together with such morphological observation.

Furthermore, in the solar cell, an electron transport layer 7, buffer layer, and second electrode 6 formed on or above a light-absorbing layer 5 can be readily removed from a substrate 1 using an organic solvent such as dimethyl sulfoxide together with the light-absorbing layer 5 because a perovskite compound in the light-absorbing layer 5 is readily dissolved in the organic solvent. Thus, elements in a second hole transport layer 32 can be determined by, for example, X-ray photoelectron spectroscopy (XPS) after a surface of the second hole transport layer 32 is exposed by removing the light-absorbing layer 5 and the layers on or above the light-absorbing layer 5 from the substrate 1. Thereafter, elements in a first hole transport layer 31 formed below the second hole transport layer 32 (that is, on the substrate 1 side) can be determined by etching off the second hole transport layer 32 using, for example, an ion beam.

### EXAMPLES

The present disclosure is described below in detail with reference to examples. Solar cells of Examples 1 to 8 and Comparative Examples 1 to 3 were prepared and were evaluated for characteristics. Elements in layers of the solar cells of Examples 1 to 8 and Comparative Examples 1 to 3 and the thickness of each layer were confirmed by cross-sectional TEM observation, EDS analysis, XPS analysis, and depth-wise elemental analysis by TOF-SIMS.

The configuration of the solar cells of Examples 1 to 8 and Comparative Examples 1 to 3 and a method for preparing each solar cell are described below. Example 1

The solar cell of Example 1 had substantially the same configuration as that of the solar cell 200 shown in FIG. 2 except that the solar cell of Example 1 included a buffer layer placed between an electron transport layer 7 and a second electrode 26. A material for each component of the solar cell of Example 1 and the thickness of the component were as described below.

Substrate 1: glass and a thickness of 0.7 mm

First electrode 2: fluorine-doped SnO₂ (a surface resistivity of 10 Ω/sq.)

First hole transport layer 31: Ni_{0.9}Li_{0.1}O and a thickness of 10 nm

Second hole transport layer 32: NiO and a thickness of 5 nm

Light-absorbing layer 5: CH₃NH₃PbI₃ and a thickness of 300 nm

Electron transport layer 7: PCBM and a thickness of 40 nm

Buffer layer: Ti_{0.9}Nb_{0.1}O₂ and a thickness of 10 nm

Second electrode 26: Al and a thickness of 100 nm

A method for preparing the solar cell of Example 1 was as described below.

First, an electrically conductive substrate having a transparent, electrically conductive layer functioning as the first electrode 2 on a surface thereof was prepared. The electrically conductive substrate was one obtained by uniting the substrate 1 and the first electrode 2. In this example, the electrically conductive substrate used was a 0.7 mm thick electrically conductive glass substrate, available from Nippon Sheet Glass Co., Ltd., having a fluorine-doped SnO₂ layer on a surface thereof.

Next, a Ni_{0.9}Li_{0.1}O layer which was the first hole transport layer 31 and which had a thickness of about 10 nm was formed on the fluorine-doped SnO₂ layer, which was the first electrode 2. The Ni_{0.9}Li_{0.1}O layer was formed by a spraying process using an aqueous solution that was prepared in such a manner that a 0.1 mol/L aqueous solution of nickel nitrate hexahydrate and a 0.1 mol/L aqueous solution of lithium nitrate were mixed so as to give a desired film composition. The temperature of the substrate 1 during spraying was 500° C.

Subsequently, a NiO layer which was the second hole transport layer 32 and which had a thickness of about 5 nm was formed on the Ni_{0.9}Li_{0.1}O layer, which was the first hole transport layer 31. In this example, the NiO layer was formed in such a manner that a 0.3 mol/L 2-methoxyethanol solution of nickel acetate tetrahydrate was applied to the Ni_{0.9}Li_{0.1}O layer by a spin coating process, followed by firing the applied solution at a temperature of 550° C. in air.

In the case where the first hole transport layer 31 and the second hole transport layer 32 are formed by a coating process, a solvent in a coating solution used to form the first hole transport layer 31 is desirably different from a solvent in a coating solution used to form the second hole transport layer 32. For example, one of the solvents may be water and the other may be an organic solvent. The solvent in the coating solution used to form the first hole transport layer 31 and the solvent in the coating solution used to form the second hole transport layer 32 are referred to as the “first solvent” and the “second solvent”, respectively. A solute in the coating solution used to form the first hole transport layer 31 and a solute in the coating solution used to form the second hole transport layer 32 are referred to as the “first solute” and the “second solute”, respectively. When the first solvent is different from the second solvent, the solubility of the first solute in the first solvent is allowed to differ from the solubility of the first solute in the second solvent. Likewise, the solubility of the second solute in the first solvent is allowed to differ from the solubility of the second solute in the second solvent. The first solute may be easily dissolved in the first solvent and may not be easily dissolved in the second solvent (that is, the solubility of the first solute in the first solvent is higher than the solubility of the first solute in the second solvent). Likewise, the second solute may be easily dissolved in the second solvent and may not be easily dissolved in the first solvent. Selecting the solvent in each coating solution as described above, a material for the first hole transport layer 31 (that is, the first solute) can be inhibited from being dissolved in the coating solution used to form the second hole transport layer 32 when the second hole transport layer 32 is formed on the first hole transport layer 31 by the coating process. Thus, a surface of the first hole transport layer 31 can be inhibited from being roughened by the dissolution of the first solute in the coating solution used to form the second hole transport layer 32. Additionally, elements making up the first hole transport layer 31 and the second hole transport layer 32 can be inhibited from segregating in the first hole transport layer 31 and the second hole transport layer 32.

Next, a CH₃NH₃PbI₃ layer which was the light-absorbing layer 5 was formed on the NiO layer, which was the second hole transport layer 32. In particular, a dimethyl sulfoxide (DMSO) solution containing PbI₂ at a concentration of 1 mol/L and methylammonium iodide (CH₃NH₃I) at a concentration of 1 mol/L was prepared. Next, the DMSO solution was applied to the substrate 1 provided with the NiO layer by a spin coating process. Thereafter, the substrate 1 was heat-treated at 100° C. on a hotplate, whereby the light-absorbing layer 5 was obtained. Incidentally, the number of revolutions of a spin coater was set such that the light-absorbing layer 5 had a thickness of about 300 nm. In order to promote the crystallization of the light-absorbing layer 5 during heat treatment, toluene was dripped onto the rotating substrate 1 after about 25 seconds from the start of spin coating.

Subsequently, a [6,6]-phenyl-C61-butyric acid methyl ester (PCBM) layer which was the electron transport layer 7 and which had a thickness of about 40 nm was formed on the CH₃NH₃PbI₃ layer, which was the light-absorbing layer 5. The PCBM layer was formed by a spin coating process using a 50 mmol/L chlorobenzene solution of PCBM.

Next, a Ti_{0.9}Nb_{0.1}O₂ layer which was the buffer layer and which had a thickness of about 10 nm was formed on the PCBM layer, which was the electron transport layer 7. The Ti_{0.9}Nb_{0.1}O₂ layer was obtained in such a manner that the following solution was applied to the PCBM layer by a spin coating process, followed by hydrolyzing the applied solution: a solution that was prepared in such a manner that a 5 μmol/L methanol solution of titanium isopropoxide and a 5 μmol/L methanol solution of niobium ethoxide were mixed so as to give a desired film composition.

The preparation of the solutions used to form the light-absorbing layer 5, the electron transport layer 7, and the buffer layer and processes such as spin coating and heat treatment were all performed in a nitrogen atmosphere in a glove box.

Finally, an Al layer which was the second electrode 26 and which had a thickness of about 100 nm was formed on the Ti_{0.9}Nb_{0.1}O₂ layer, which was the buffer layer, by resistive heating evaporation. In this way, the solar cell of Example 1 was obtained.

### Example 2

The solar cell of Example 2 was prepared by substantially the same method as that used in Example 1 except that a formed second hole transport layer 32 was a Ni_{0.95}Li_{0.05}O layer with a thickness of about 5 nm. The Ni_{0.95}Li_{0.05}O layer was formed in such a manner that the following solution was applied to a Ni_{0.9}Li_{0.1}O layer which was a first hole transport layer 31 by a spin coating process, followed by firing at 550° C. in air: a solution that was prepared in such a manner that a 0.3 mol/L 2-methoxyethanol solution of nickel acetate tetrahydrate and a 0.3 mol/L 2-methoxyethanol solution of lithium acetate dihydrate were mixed so as to give a desired film composition. Components other than the second hole transport layer 32 were the same as those formed in Example 1.

### Example 3

The solar cell of Example 3 was prepared by substantially the same method as that used in Example 1 except that a formed first hole transport layer 31 was a Ni_{0.8}Li_{0.2}O layer with a thickness of about 10 nm and a formed second hole transport layer 32 was a Ni_{0.9}Li_{0.1}O layer with a thickness of about 5 nm. The Ni_{0.8}Li_{0.2}O layer, which was the first hole transport layer 31, was formed by a spraying process using an aqueous solution that was prepared in such a manner that a 0.1 mol/L aqueous solution of nickel nitrate hexahydrate and a 0.1 mol/L aqueous solution of lithium nitrate were mixed so as to give a desired film composition. The Ni_{0.9}Li_{0.1}O layer, which was the second hole transport layer 32, was formed in such a manner that the following solution was applied to the Ni_{0.8}Li_{0.2}O layer by a spin coating process, followed by firing at 550° C. in air: a solution that was prepared in such a manner that a 0.3 mol/L 2-methoxyethanol solution of nickel acetate tetrahydrate and a 0.3 mol/L 2-methoxyethanol solution of lithium acetate dihydrate were mixed so as to give a desired film composition. Components other than the first hole transport layer 31 and the second hole transport layer 32 were the same as those formed in Example 2.

### Example 4

The solar cell of Example 4 was prepared by substantially the same method as that used in Example 1 except that a formed second hole transport layer 32 was a Ni_{0.8}Mg_{0.2}O layer with a thickness of about 5 nm. The Ni_{0.8}Mg_{0.2}O layer was formed in such a manner that the following solution was applied by a spin coating process, followed by firing at 550° C. in air: a solution that was prepared in such a manner that a 0.3 mol/L 2-methoxyethanol solution of nickel acetate tetrahydrate and a 0.3 mol/L 2-methoxyethanol solution of magnesium acetate tetrahydrate were mixed so as to give a desired film composition. Components other than the second hole transport layer 32 were the same as those formed in Example 1.

### Example 5

The solar cell of Example 5 was prepared by substantially the same method as that used in Example 1 except that a formed first hole transport layer 31 was a Ni_{0.8}Li_{0.1}Mg_{0.1}O layer with a thickness of about 10 nm and a formed second hole transport layer 32 was a Ni_{0.9}Mg_{0.1}O layer with a thickness of about 5 nm. The Ni_{0.8}Li_{0.1}Mg_{0.1}O layer was formed by a spraying process using an aqueous solution that was prepared in such a manner that a 0.1 mol/L aqueous solution of nickel nitrate hexahydrate, a 0.1 mol/L aqueous solution of lithium nitrate, and a 0.1 mol/L aqueous solution of magnesium nitrate hexahydrate were mixed so as to give a desired film composition. The Ni_{0.9}Mg_{0.1}O layer was formed in such a manner that the following solution was applied by a spin coating process, followed by firing at 550° C. in air: a solution that was prepared in such a manner that a 0.3 mol/L 2-methoxyethanol solution of nickel acetate tetrahydrate and a 0.3 mol/L 2-methoxyethanol solution of magnesium acetate tetrahydrate were mixed so as to give a desired film composition. Components other than the first hole transport layer 31 and the second hole transport layer 32 were the same as those formed in Example 1.

### Example 6

The solar cell of Example 6 was prepared by substantially the same method as that used in Example 1 except that a formed first hole transport layer 31 was a Ni_{0.7}Li_{0.2}Mg_{0.1}O layer with a thickness of about 10 nm and a formed second hole transport layer 32 was a Ni_{0.75}Li_{0.15}Mg_{0.1}O layer with a thickness of about 5 nm. The Ni_{0.7}Li_{0.2}Mg_{0.1}O layer was formed by a spraying process using an aqueous solution that was prepared in such a manner that a 0.1 mol/L aqueous solution of nickel nitrate hexahydrate, a 0.1 mol/L aqueous solution of lithium nitrate, and a 0.1 mol/L aqueous solution of magnesium nitrate hexahydrate were mixed so as to give a desired film composition. The Ni_{0.75}Li_{0.15}Mg_{0.1}O layer was formed in such a manner that the following solution was applied by a spin coating process, followed by firing at 550° C. in air: a solution that was prepared in such a manner that a 0.3 mol/L 2-methoxyethanol solution of nickel acetate tetrahydrate, a 0.3 mol/L 2-methoxyethanol solution of lithium acetate dihydrate, and a 0.3 mol/L 2-methoxyethanol solution of magnesium acetate tetrahydrate were mixed so as to give a desired film composition. Components other than the first hole transport layer 31 and the second hole transport layer 32 were the same as those formed in Example 1.

### Example 7

The solar cell of Example 7 was prepared by substantially the same method as that used in Example 1 except that the thickness of a first hole transport layer 31 was set to about 5 nm and the thickness of a second hole transport layer 32 was set to about 3 nm. A configuration other than the thickness of the first hole transport layer 31 and the thickness of the second hole transport layer 32 was the same as that described in Example 1.

### Example 8

The solar cell of Example 8 was prepared by substantially the same method as that used in Example 1 except that the thickness of a first hole transport layer 31 was set to about 15 nm and the thickness of a second hole transport layer 32 was set to about 10 nm. A configuration other than the thickness of the first hole transport layer 31 and the thickness of the second hole transport layer 32 was the same as that described in Example 1.

### Comparative Example 1

The solar cell of Comparative Example 1 had substantially the same configuration as that of the solar cell of Example 1 except that the solar cell of Comparative Example 1 included no second hole transport layer 32. A material for each component of the solar cell of Comparative Example 1 and the thickness of the component were as described below.

Substrate 1: glass and a thickness of 0.7 mm

First electrode 2: fluorine-doped SnO₂ (a surface resistivity of 10 Ω/sq.)

First hole transport layer 31: Ni_{0.9}Li_{0.1}O and a thickness of 10 nm

Light-absorbing layer 5: CH₃NH₃PbI₃ and a thickness of 300 nm

Electron transport layer 7: PCBM and a thickness of 40 nm

Buffer layer: Ti_{0.9}Nb_{0.1}O₂ and a thickness of 10 nm

Second electrode 26: Al and a thickness of 100 nm

A method for preparing the solar cell of Comparative Example 1 was as described below.

First, the first hole transport layer 31 was formed above an electrically conductive substrate having the first electrode 2 on a surface thereof in the same manner as that used in Example 1.

Next, a CH₃NH₃PbI₃ layer which was the light-absorbing layer 5 and which had a thickness of about 300 nm was formed on a Ni_{0.9}Li_{0.1}O layer which was the first hole transport layer 31 in the same manner as that used in Example 1. Thereafter, the electron transport layer 7, the buffer layer, and the second electrode 26 were formed in the same manner as that used in Example 1, whereby the solar cell of Comparative Example 1 was obtained.

### Comparative Example 2

The solar cell of Comparative Example 2 was prepared by substantially the same method as that used in Comparative Example 1 except that a formed first hole transport layer 31 was a Ni_{0.8}Li_{0.2}O layer with a thickness of about 10 nm. Components other than the first hole transport layer 31 were the same as those formed in Comparative Example 1.

### Comparative Example 3

The solar cell of Comparative Example 3 was prepared by substantially the same method as that used in Comparative Example 1 except that a formed first hole transport layer 31 was a Ni_{0.8}Li_{0.1}Mg_{0.1}O layer with a thickness of about 10 nm. Components other than the first hole transport layer 31 were the same as those formed in Comparative Example 1.

### Depth-Wise Elemental Analysis by TOF-SIMS

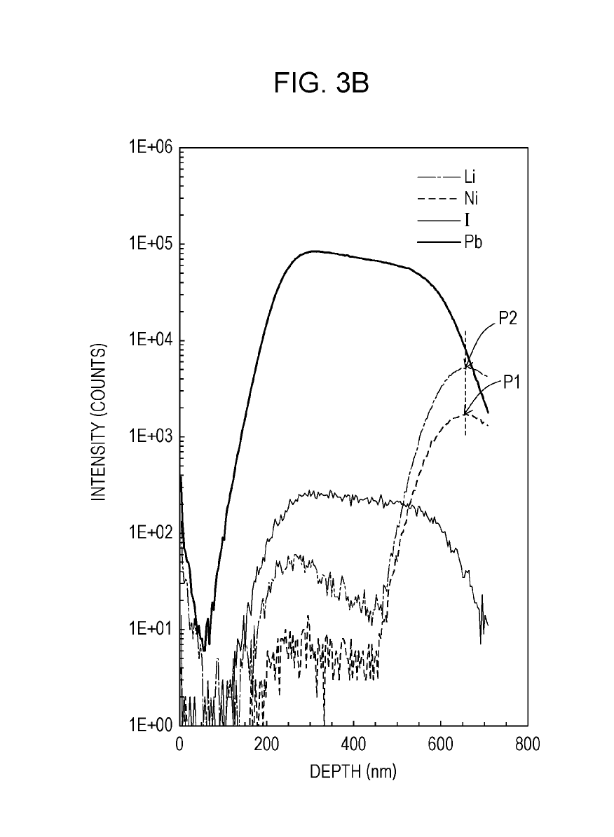

FIGS. 3A and 3B are graphs showing results obtained by analyzing elements in the solar cell of Example 1 and the solar cell of Comparative Example 1, respectively, in the depth direction by TOF-SIMS. In FIGS. 3A and 3B, the horizontal axis represents the depth from a surface of a second electrode and the vertical axis represents the intensity (the number of ion counts).

As shown in FIG. 3A, in the concentration profiles of Ni and Li in the depth direction of the solar cell of Example 1, Peak P1 corresponding to Ni is located closer to the light-absorbing layer 5 than Peak P2 corresponding to Li. As shown in FIG. 3B, the concentration profiles of Ni and Li in the solar cell of Comparative Example 1 have Peaks P1 and P2 at substantially the same depth. Thus, this analysis method shows that, in the case where, for example, a hole transport layer 3 is formed using NiO or a material obtained by adding Li to NiO, the amount of added Li is less on the light-absorbing layer 5 side than on the second electrode 26 side. Incidentally, the hole transport layer 3 formed in each of Examples 1 to 8 has a multilayer structure including two layers having different compositions. Even in the case where the hole transport layer 3 is formed such that the lithium ratio decreases stepwise or continuously from the substrate 1 side toward the light-absorbing layer 5 side as described above, the variation of the lithium ratio in the hole transport layer 3 in the depth direction can be confirmed by this analysis method. Herein, SIMS is used. However, another method may be used for elemental analysis in the depth direction.

### Evaluation of Solar Cells

The solar cells of Examples 1 to 8 and Comparative Examples 1 to 3 were irradiated with light with an irradiance of 100 mW/cm² using a solar simulator and were measured for current-voltage characteristic. Furthermore, the open-circuit voltage (V), short-circuit current density (mA/cm²), fill factor, and conversion efficiency (%) of each solar cell were determined from the current-voltage characteristic thereof after stabilization.

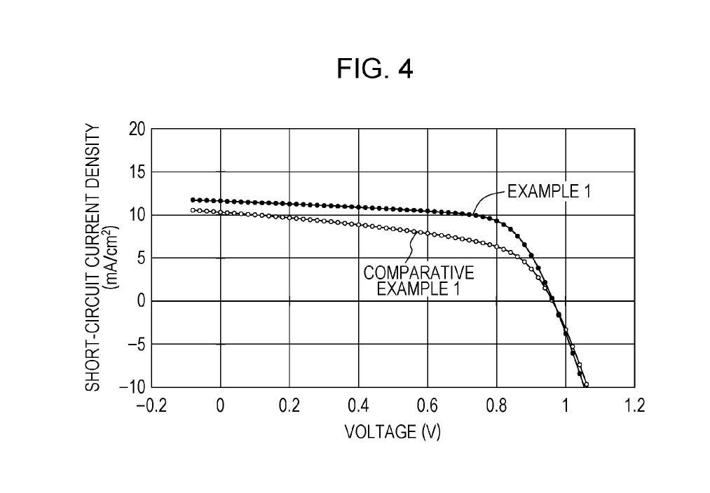

Evaluation results are shown in the table. Furthermore, measurement results of the current-voltage characteristic of the solar cells of Example 1 and Comparative Example 1 are shown in FIG. 4.

TABLE

| | | | | | Short- | | | |
|---|---|---|---|---|---|---|---|---|
| | | | | | circuit | Open- | | |
| | First hole transport | | Second hole transport | | current | circuit | | Conversion |
| | layer 31 | | layer 32 | | density | voltage | Fill | efficiency |
| | Thickness | Composition | Thickness | Composition | (mA/cm²) | (V) | factor | (%) |
| Example 1 | 10 nm | Ni_{0.9}Li_{0.1}O | 5 nm | NiO | 11.6 | 0.96 | 0.67 | 7.5 |
| Example 2 | 10 nm | Ni_{0.9}Li_{0.1}O | 5 nm | Ni_{0.95}Li_{0.05}O | 11.9 | 0.95 | 0.69 | 7.8 |
| Example 3 | 10 nm | Ni_{0.8}Li_{0.2}O | 5 nm | Ni_{0.9}Li_{0.1}O | 11.7 | 0.93 | 0.70 | 7.6 |
| Example 4 | 10 nm | Ni_{0.9}Li_{0.1}O | 5 nm | Ni_{0.8}Mg_{0.2}O | 11.8 | 0.98 | 0.66 | 7.6 |
| Example 5 | 10 nm | Ni_{0.8}Li_{0.1}Mg_{0.1}O | 5 nm | Ni_{0.9}Mg_{0.1}O | 11.6 | 0.99 | 0.65 | 7.5 |
| Example 6 | 10 nm | Ni_{0.7}Li_{0.2}Mg_{0.1}O | 5 nm | Ni_{0.75}Li_{0.15}Mg_{0.1}O | 12.0 | 0.97 | 0.68 | 7.9 |
| Example 7 | 5 nm | Ni_{0.9}Li_{0.1}O | 3 nm | NiO | 11.3 | 0.96 | 0.67 | 7.3 |
| Example 8 | 15 nm | Ni_{0.9}Li_{0.1}O | 10 nm | NiO | 11.5 | 0.95 | 0.65 | 7.1 |
| Comparative | 10 nm | Ni_{0.9}Li_{0.1}O | — | — | 10.3 | 0.96 | 0.52 | 5.1 |
| Example 1 | | | | | | | | |
| Comparative | 10 nm | Ni_{0.8}Li_{0.2}O | — | — | 10.1 | 0.95 | 0.54 | 5.2 |
| Example 2 | | | | | | | | |
| Comparative | 10 nm | Ni_{0.8}Li_{0.1}Mg_{0.1}O | — | — | 10.4 | 0.98 | 0.51 | 5.2 |
| Example 3 | | | | | | | | |

As is clear from the table, the solar cells of Examples 1 to 8 that included the second hole transport layers 32 exhibited good results, that is, a short-circuit current density of greater than 11 mA/cm² and a conversion efficiency of greater than 7%. However, the solar cells of Comparative Examples 1 to 3 that included no second hole transport layer 32 exhibited a short-circuit current density and conversion efficiency lower than those of the solar cells of Examples 1 to 8.

From the above results, it is confirmed that placing a second hole transport layer having a lithium ratio less than that of a first hole transport layer on the light-absorbing layer side of the first hole transport layer allows a solar cell having an inverted stack structure to have increased photoelectric conversion efficiency. Incidentally, even when a hole transport layer does not have the above multilayer structure, a similar effect is obtained if the lithium ratio in the depth direction of the hole transport layer is less on the light-absorbing layer side than on the substrate side.

A solar cell according to the present disclosure is useful as, for example, a solar battery placed on a roof and is also useful as a photodetector. The solar cell can be used for image sensing.

What is claimed is:

1. A solar cell comprising:
a first electrode;
a hole transport layer containing nickel, lithium, and oxygen;
a light-absorbing layer converting light into electric charge; and
a second electrode, wherein
the first electrode, the hole transport layer, the light-absorbing layer, and the second electrode are layered in that order,
the light-absorbing layer contains a perovskite compound represented by a formula AMX₃, where A is a monovalent cation, M is a divalent cation, and X is a monovalent anion, and
a concentration of lithium in a first portion of the hole transport layer is less than a concentration of lithium in a second portion of the hole transport layer, the first portion facing the light-absorbing layer, the second portion facing the first electrode.

2. The solar cell according to claim 1, wherein
the hole transport layer includes a first hole transport layer located on a side of the first electrode and a second hole transport layer located on a side of the light-absorbing layer, and
an atomic ratio of lithium to all metal elements in the second hole transport layer is less than an atomic ratio of lithium to all metal elements in the first hole transport layer.

3. The solar cell according to claim 1, wherein
the hole transport layer includes a first hole transport layer located on a side of the first electrode and a second hole transport layer located on a side of the light-absorbing layer,
the first hole transport layer contains lithium, and
the second hole transport layer contains substantially no lithium.

4. The solar cell according to claim 2, wherein at least either the first hole transport layer or the second hole transport layer further contains magnesium.

5. The solar cell according to claim 2, wherein a thickness of the second hole transport layer is less than a thickness of the first hole transport layer.

6. The solar cell according to claim 2, wherein a thickness of the second hole transport layer is 1 nm or more and 10 nm or less.

7. The solar cell according to claim 6, wherein the thickness of the second hole transport layer is 2 nm or more and 5 nm or less.

8. The solar cell according to claim 2, wherein an atomic ratio of lithium to all the metal elements in the first hole transport layer is 1% or more and 30% or less.

9. The solar cell according to claim 8, wherein the atomic ratio of lithium to all the metal elements in the first hole transport layer is 5% or more and 20% or less.

10. The solar cell according to claim 1, wherein in concentration profiles of nickel and lithium in a depth direction of the hole transport layer, a peak corresponding to nickel is located closer to the light-absorbing layer than a peak corresponding to lithium is.

11. A solar cell comprising:
a first electrode;
a hole transport layer containing nickel, lithium, and oxygen;
a light-absorbing layer converting light into electric charge; and
a second electrode, wherein
the first electrode, the hole transport layer, the light-absorbing layer, and the second electrode are layered in that order,
the light-absorbing layer contains a perovskite compound represented by a formula AMX₃, where A is a monovalent cation, M is a divalent cation, and X is a monovalent anion, and
in concentration profiles of nickel and lithium in a depth direction of the hole transport layer, a peak corresponding to nickel is located closer to the light-absorbing layer than a peak corresponding to lithium is.
